(19) United States
(12) Patent Application Publication
(10) Pub. No.: US 2025/0312776 A1
(43) Pub. Date: Oct. 9, 2025

(54) CATALYST AND METHOD FOR CONVERTING CO2 TO SOLID CARBON, AND COMPOSITES INCLUDING SOLID CARBON

(71) Applicant: Washington University, St. Louis, MO (US)

(72) Inventors: Xinhua LIANG, St. Louis, MO (US); Kaiying WANG, St. Louis, MO (US)

(21) Appl. No.: 19/170,154

(22) Filed: Apr. 4, 2025

Related U.S. Application Data
(60) Provisional application No. 63/575,268, filed on Apr. 5, 2024.

(51) Int. Cl. B01J 23/78; B01J 23/755; B01J 23/83; B01J 23/86; B01J 35/30; B01J 37/02; B01J 37/03; B01J 37/10; C01B 3/26; C01B 32/162; C04B 35/528; C04B 35/628; C04B 35/64; C23C 16/26; C23C 16/56

(52) U.S. Cl. CPC B01J 23/78; B01J 23/755; B01J 23/83; B01J 23/866; B01J 35/395; B01J 35/397; B01J 37/0201; B01J 37/0236; B01J 37/031; B01J 37/036; B01J 37/10; C01B 3/26; C01B 32/162; C04B 35/528; C04B 35/62839; C04B 35/62884; C04B 35/62892; C04B 35/64; C23C 16/26; C23C 16/56; C01B 2203/0277; C01B 2203/1058; C01B 2203/1241; C01P 2004/03; C01P 2004/04; C01P 2004/13; C04B 2235/427

(57) ABSTRACT

Described herein are catalysts, methods of making same, and methods of using same. The catalysts are especially useful for converting CO₂ to solid carbon. Also described herein are carbon nanoproduct reinforced composites and methods of using same.

### CROSS-REFERENCE TO RELATED APPLICATIONS

This application claims priority to U.S. Provisional Patent Application No. 63/575,268, filed on Apr. 5, 2024, the contents of which are hereby incorporated by reference herein.

### GOVERNMENT SUPPORT CLAUSE

This invention was made with government support under CBET1803812 and CBET2306177 awarded by the National Science Foundation. The government has certain rights in the invention.

### BACKGROUND

The escalating climate crisis has prompted the scientific community to diligently explore sustainable solutions for mitigating carbon dioxide (CO₂) emissions and transitioning towards a carbon-neutral future. Among these innovative approaches, converting CO₂ to value-added solid carbon has emerged as a promising technology that holds significant potential in addressing the dual challenges of carbon emission and carbon storage.

There are different technologies for converting CO₂ to solid carbon, but all conventional technologies face significant limitations. For example, the direct thermocatalytic conversion of CO₂ to solid carbon faces significant thermodynamic challenges, limiting its practical application. Current research on direct CO₂ valorization into solid carbon products is in its nascent stages, with notable approaches including electrochemical reduction using Galinstan-based liquid metals and CO₂ electrolysis in molten lithium bicarbonate. However, these methods have been hampered by several obstacles, including low yields, amorphous carbon morphology, and insufficient current densities (typically below 10 mA·cm⁻²). Recent advancements have explored a two-step process, combining electrochemical reduction of CO₂ to CO followed by thermochemical conversion of CO to solid carbon via the Boudouard reaction. However, this approach is constrained by thermodynamic limitations, as the conversion of two moles of CO to solid carbon releases one mole of CO₂, resulting in a maximum theoretical CO₂ conversion efficiency of 50% in a single pass.

Given these limitations, there is a critical need for novel methodologies that enable large-scale conversion of CO₂ into value-added solid carbon products under mild conditions. Such methods should seamlessly integrate with renewable energy sources and demonstrate compatibility with existing infrastructure. The development of an integrated CO₂-to-solid-carbon pathway herein aims to showcase a scalable approach to CO₂ utilization that not only contributes to carbon sequestration, but also yields high-value materials, potentially offering a more economically viable route for large-scale CO₂ conversion. This approach aligns with the growing demand for carbon materials in advanced applications and could provide a sustainable source for these materials while simultaneously addressing CO₂ emissions. By overcoming the current limitations and inefficiencies in CO₂ conversion processes, this approach has the potential to revolutionize carbon capture and utilization technologies, paving the way for more effective climate change mitigation strategies and the development of a circular carbon economy.

The disclosed tandem catalytic processes to convert CO₂ to solid carbon using methane (CH₄) as an intermediate has significant advantages compared to the state-of-the-art technologies. This process includes three steps: (1) CO₂ hydrogenation to form methane using a catalytic reactor, (2) CH₄ catalytic decomposition to form solid carbon nanoproducts (CNPs) and hydrogen (H₂), and (3) separation of H₂ and unreacted CH₄, which will be recycled for CO₂ hydrogenation and CH₄ decomposition, respectively. H₂O produced in the first reaction can be used to produce H₂ and O₂ via electrolysis using renewable electricity. CH₄ is selected as the intermediate because of the high conversion and high yield of products in both reactions. Though H₂ from CH₄ decomposition will be separated and recycled for CO₂ hydrogenation, additional 50% of H₂ needs to be provided, due to the converting of H₂ to water in the CO₂ hydrogenation process.

There is no known report about converting CO₂ to solid carbon using CH₄ as an intermediate. The present high-performance nickel (Ni) based catalysts for CH₄ synthesis and CH₄ decomposition can significantly increase the catalytic activity, catalyst lifetime, and CNPs yield (e.g., g_{CNP}/g_{catalyst}). In addition, the two steps of the process are both gas-solid heterogeneous thermal catalysis, which are more suitable to operate continuously and easier to scale up. The catalysts used in the process are all non-noble metal, and no molten salt and liquid metals are needed.

CO₂ methanation involves the catalytic conversion of CO₂ and H₂ into CH₄, a versatile energy carrier and an environmentally benign alternative to conventional fossil fuels. The efficiency and selectivity of this reaction are highly dependent on the choice of catalysts, which play a crucial role in facilitating the reaction, lowering the activation energy, and determining the overall performance of the process. Several types of catalysts have been investigated for CO₂ methanation, and some of the most common ones are Ni, Co, Ru, Pt, and Rh catalysts. Among these catalysts, Ni catalysts are widely used in CO₂ methanation, since Ni is abundant and relatively cost-effective. Besides, Ni possesses a high catalytic activity for the dissociation of CO₂ and the subsequent hydrogenation to form methane.

Despite the advantages, challenges remain for Ni catalysts in CO₂ methanation. For instance, Ni catalysts are sensitive to carbon deposition (coking), which can inhibit their catalytic activity. Sintering, a prevalent mechanism of catalyst deactivation, pertains to the progressive aggregation and coalescence of catalyst particles at elevated temperatures, leading to a diminished performance of Ni catalysts. An effective strategy to mitigate sintering is to lower the reaction temperature, which also thermodynamically disfavors CO formation. Therefore, designing a catalyst with high activity at low temperatures is imperative.

The catalytic performance of Ni-based CO₂ methanation catalysts strongly depends on the properties of the support material. Many substrates, including SiO₂, Al₂O₃, CeO₂, MgO, TiO₂, ZrO₂ and zeolite, have been employed for CO₂ methanation in recent years. Among these, MgO is a commonly used substrate for Ni due to its ability to form solid solutions with NiO, stemming from the comparable lattice parameters of NiO (4.17 Å) and MgO (4.21 Å). The formation of NiO—MgO solid solution facilitates various catalytic processes like hydrogenation, reforming, and syngas production. The synthesis conditions significantly influence the extent of NiO—MgO solid solution formation, including calcination temperature, Ni loading, etc. The reducibility of Ni²⁺ within the solid solution also relies on the position of Ni²⁺ in the MgO lattice and metal-support interactions. Besides, the Ni—MgO interface and interactions are governed by the synthesis method. Among various synthesis techniques, sol-gel method offers control over the catalyst's structure and morphology, influencing its performance by optimizing basicity and oxygen vacancy formation.

The presence of oxygen vacancies in metal oxide catalysts plays an important role in enhancing the catalytic activity for low temperature CO₂ methanation. Several studies demonstrated that increasing the concentration of oxygen vacancies in catalysts like CeO₂ and ZrO₂ led to improved CO₂ conversion and CH₄ selectivity. The oxygen vacancies introduce localized electron-rich sites that can facilitate CO₂ activation and hydrogenation.

In summary, CO₂ methanation catalysts have seen significant advancements through multiple optimization strategies. Ni-based catalysts remain the most practical option due to their abundance and cost-effectiveness, though they face challenges like coking and sintering. Support materials, particularly MgO which forms solid solutions with NiO, play a crucial role in catalyst performance. Interface engineering between metal nanoparticles and supports has yielded exceptional conversion rates and selectivity. This disclosure aims to develop more efficient and durable catalysts for sustainable CO₂ conversion by engineering of oxygen vacancies to creates electron-rich sites that facilitate CO₂ activation and hydrogenation at lower temperatures.

Further, the catalytic decomposition of methane (CDM) faces several significant challenges that have limited its industrial implementation despite its potential for producing CO-free hydrogen and valuable carbon materials. The primary challenge in methane decomposition is catalyst deactivation, which occurs through multiple pathways. When carbon accumulates on the catalyst surface, it can lead to encapsulation of the active metal sites, preventing further methane adsorption. This deactivation typically follows two distinct regimes: an initial rapid deactivation followed by a slower, irreversible deactivation phase. The degree of graphitization of the deposited carbon significantly impacts catalyst longevity, with highly graphitized carbon being a key factor contributing to deactivation of the catalysts. The rate of carbon formation versus carbon diffusion through the catalyst is critical. When carbon formation exceeds the diffusion rate, it accumulates on the catalyst surface, leading to deactivation. This balance is highly temperature-dependent, with higher temperatures promoting both faster carbon formation and diffusion.

Methane decomposition is endothermic (ΔH₂₉₈_{ₖ}=75.6 kJ/mol), requiring significant energy input. While non-catalytic thermal decomposition requires temperatures above 900° C., catalysts can lower the temperature of this decomposition reaction to 700-800° C., but maintaining optimal reaction temperatures presents challenges in heat management and energy efficiency. The reaction follows Le Chatelier's principle, where low pressure and high temperature drive the forward reaction. However, these conditions also accelerate catalyst deactivation through sintering and phase separation at elevated temperatures. For instance, at high temperatures, fragmentation and phase separation contribute to carbon atom enrichment and increased graphitization, which accelerates catalyst deactivation.

Developing stable, high-performance catalysts remains challenging. While Ni-based catalysts show high initial activity, they often suffer from deactivation over time. Fe and Co catalysts demonstrate better stability but lower activity. The metal-support interaction significantly influences catalyst performance and carbon formation mechanisms, with stronger interactions generally promoting better stability. Bimetallic catalysts show promise for enhancing stability and activity. For example, Fe—Mo bimetallic catalysts on activated carbon have achieved up to 90% conversion with improved stability at 950° C. However, optimizing the metal ratios and ensuring proper dispersion remains complex, as excess promoter metals can lead to segregation and reduced effectiveness. The type of carbon formed during CDM (nanotubes, nanofibers, amorphous carbon) significantly affects catalyst performance. While some carbon structures (like filamentous carbon) can grow away from the catalyst surface allowing continued activity, others encapsulate and deactivate the catalyst. The growth mechanism (tip vs. base growth) depends on the metal-support interaction strength and affects both catalyst regenerability and carbon harvesting. Developing methods for continuous carbon removal or catalyst regeneration without disrupting the reaction presents another significant challenge. While some recent approaches show promise, such as using induction heating to promote an autocatalytic effect with carbon-based catalysts, implementing these at industrial scale remains difficult. These multifaceted challenges require integrated approaches to catalyst design, reactor engineering, and process optimization to make methane decomposition a viable industrial process for hydrogen production and carbon sequestration.

Still further, the integration of carbon nanotubes (CNTs) or carbon nanofibers (CNFs) into ceramic matrices presents significant potential for enhancing mechanical, thermal, and electrical properties of composite materials. However, achieving uniform distribution of these reinforcing agents within ceramic oxide matrices remains one of the most challenging aspects in the manufacturing of high-performance CNT-ceramic composites. While conventional mechanical mixing methods often result in agglomeration and structural damage, emerging approaches leveraging catalytic nanoparticles for in-situ growth of CNTs/CNFs present a transformative solution. Conventional mechanical mixing techniques often fail to achieve uniform dispersion of CNTs within ceramic matrices due to the inherent physical properties of CNTs. CNTs possess extremely high specific surface areas and strong attractive van der Waals forces between individual tubes, making them highly prone to agglomeration. These agglomerates act as structural defects within the final composite, creating stress concentration points that significantly degrade mechanical properties. Traditional ball milling processes, while widely used for mixing CNTs with ceramic powders, demonstrate significant limitations in achieving homogeneous dispersion. Even with optimized ball-to-powder weight ratios (typically 2:1 to 15:1) and milling speeds (200-600 rpm), ball milling processes often result in non-uniform distributions, particularly at higher CNT concentrations. The mechanical forces applied during conventional mixing processes frequently damage the structural integrity of CNTs. Ball milling, for instance, can contaminate powders and damage CNT walls due to high pressure during collisions, presenting a critical trade-off between distribution and structural integrity. This damage compromises the extraordinary intrinsic properties of CNTs that make them desirable as reinforcing agents in the first place. Solution-based approaches, including ultrasonication and stirring, attempt to address these issues by dispersing CNTs in solvents before mixing with ceramic powders. However, longer ultrasonication times (up to 120 minutes) improved aqueous dispersion of functionalized CNTs, no significant increases in the compressive and flexural strengths of the resulting composites. This suggests that achieving good dispersion in the liquid phase does not necessarily translate to improved mechanical properties in the final sintered composite. Poor interfacial bonding between CNTs and ceramic matrices represents another critical limitation. Conventional mixing approaches typically result in physical rather than chemical bonding between components, leading to weak interfaces that fail to effectively transfer load between the matrix and reinforcement. Analysis of fracture surfaces from conventionally mixed composites often reveals loosely aligned CNTs, indicating poor bonding with the ceramic matrix. This weak interfacial adhesion facilitates crack propagation and hampers toughening mechanisms like crack bridging, undermining the potential reinforcement effects of CNTs.

Thus, there exists a need for catalytic systems and processes to overcome previous challenges and efficiently convert carbon dioxide to value-added materials.

### BRIEF DESCRIPTION

In one embodiment of the present disclosure, provided herein is a method of converting CO₂ to solid carbon, the method comprising: a first step of catalytically methanating CO₂ to form CH₄; and a second step of catalytically decomposing the CH₄ to form carbon nanoproducts (CNPs) and H₂.

In another embodiment of the present disclosure, provided herein is a method comprising: depositing catalytic particles on substrate particles; and using the catalytic particles to grow carbon nanoproducts on the substrate particles.

In yet another embodiment of the present disclosure, provided herein is a method to produce a composite, comprising: depositing highly dispersed nanoparticle (NP) catalysts on substrate particles; growing carbon nanoproducts (CNPs) on the substrate particles using CH₄ decomposition catalyzed by the NPs to form CNP-particles; leaching the NP catalysts from the CNP-particles using an acid solution; and sintering the CNP-particles to form a composite including CNPs grown uniformly on surfaces of the substrate particles of the composite.

### BRIEF DESCRIPTION OF DRAWINGS

These and other features, aspects, and advantages of the present disclosure will become better understood when the following detailed description is read with reference to the accompanying drawings. These drawings are exemplary and are not to be construed as limiting.

FIG. 1 depicts a schematic of continuous production, including a fluidized bed reactor for CNTs/H₂ production in accordance with the present disclosure.

FIG. 2 depicts a schematic representative of the integrated system in accordance with the present disclosure.

FIG. 3a depicts the effects of temperature (200-450° C.) on CO₂ conversion under 14.5 psi and GHSV of 9 L·g⁻¹·h⁻¹ in accordance with the present disclosure.

FIG. 3b depicts a comparison of low temperature (200-300° C.) performance of Ni—MgO catalysts in accordance with the present disclosure.

FIG. 4 depicts CO₂ conversion and CH₄ selectivity using Ni—MgO—SG catalyst under different values of pressure and GHSV at 300° C. in accordance with the present disclosure.

FIG. 5a depicts an Arrhenius plot of Ni—MgO catalysts for CO₂ methanation in accordance with the present disclosure.

FIG. 5b depicts a stability test of Ni—MgO—SG catalyst in CO₂ methanation at 300° C. and 36 L·g⁻¹·h⁻¹ in accordance with the present disclosure.

FIG. 5c depicts a representative STEM-HAADF (scanning transmission electron microscope—high-angle annular dark-field imaging) image of Ni—MgO—SG after 200 hours' stability test in accordance with the present disclosure.

FIG. 5d depicts TGA (Thermogravimetric Analysis) profiles of Ni—MgO—SG after 200 hours' stability test in accordance with the present disclosure.

FIG. 6a depicts CO₂ methanation performance of Ni₈₇CeₓZr₁₃₋_{ₓ}-SG (x=0, 6.5) catalysts and NiO at 200-300° C. with GHSV=15,000 mL/(g·h) in accordance with the present disclosure.

FIG. 6b depicts a stability test of Ni₈₇Ce_{6.5}Zr_{6.5}-SG at 250° C. with GHSV=15,000 mL/(g·h) in accordance with the present disclosure.

FIG. 7a depicts methane pyrolysis performance of ion exchange prepared samples and deposition-precipitation samples at 600° C. with GHSV=12,000 mL·g⁻¹·h⁻¹ in accordance with the present disclosure.

FIG. 7b depicts methane pyrolysis performance of ion exchange prepared samples and deposition-precipitation samples at 600° C. with GHSV=48,000 mL·g⁻¹·h⁻¹ in accordance with the present disclosure.

FIG. 7c depicts a TEM image of the obtained carbon materials in accordance with the present disclosure.

FIG. 7d depicts a TEM image of the obtained carbon materials in accordance with the present disclosure.

FIG. 7e depicts an SEM image of the obtained carbon materials in accordance with the present disclosure.

FIG. 7f depicts an SEM image of the obtained carbon materials in accordance with the present disclosure.

FIG. 8a depicts a STEM image of diamond particle (4-8 μm) coated by 100 cycles of nickel oxide ALD in accordance with the present disclosure.

FIG. 8b depicts an EDS spectrum of the NiO nanoparticles (position 1) in accordance with the present disclosure.

FIG. 9a depicts a TEM of obtained CNTs on Ni-diamond surface under a first magnification in accordance with the present disclosure.

FIG. 9b depicts a TEM of obtained CNTs on Ni-diamond surface under a second magnification in accordance with the present disclosure.

FIG. 9c depicts a TEM of obtained CNTs on Ni-diamond surface under a third magnification in accordance with the present disclosure.

FIG. 10 depicts methane conversion using stainless-steel particles at 800° C. in accordance with the present disclosure.

FIG. 11a depicts methane conversion using steel wool at 800° C. in accordance with the present disclosure.

FIG. 11b depicts a TEM image of the obtained solid carbon at 800° C. in accordance with the present disclosure.

FIG. 12a depicts methane conversion using steel slags at different temperatures in accordance with the present disclosure.

FIG. 12b depicts an SEM image of the obtained solid carbon at 800° C. in accordance with the present disclosure.

FIG. 13 depicts a schematic of the tandem process of CO₂ to solid carbon in accordance with the present disclosure.

FIG. 14a depicts CO₂ conversion efficiency and gas-phase carbon balance during tandem catalytic conversion of CO₂ to solid carbon, under reaction conditions: Feed gas flow rates (CO₂:H₂:N₂=12:48:10 mL/min), with Reactor 1 temperature held constant at 250° C. and H₂SO₄ for water removal, in accordance with the present disclosure.

FIG. 14b depicts accumulated solid carbon mass after 12 hours of continuous operation at varied reaction temperatures in accordance with the present disclosure.

FIG. 14c depicts an SEM image of solid carbon obtained at 550° C. in accordance with the present disclosure.

FIG. 14d depicts an SEM image of solid carbon obtained at 600° C. in accordance with the present disclosure.

FIG. 14e depicts an SEM image of solid carbon obtained at 650° C. in accordance with the present disclosure.

FIG. 14f depicts an SEM image of solid carbon obtained at 700° C. in accordance with the present disclosure.

FIG. 15a depicts a schematic of a conventional nanocomposite.

FIG. 15b depicts a schematic of a nanocomposite in accordance with the present disclosure.

FIG. 16 depicts a schematic of the process in accordance with the present disclosure.

Unless otherwise indicated, the drawings provided herein are meant to illustrate features of embodiments of the disclosure. These features are believed to be applicable in a wide variety of systems comprising one or more embodiments of the disclosure. As such, the drawings are not meant to include all conventional features known by those of ordinary skill in the art to be required for the practice of the embodiments disclosed herein.

### DETAILED DESCRIPTION

Disclosed herein is an integrated process for converting carbon dioxide to high-value carbon nanoproducts through a two-step tandem catalytic process. The first step employs low-temperature CO₂ methanation using a nickel-based catalyst, converting carbon dioxide to methane under mild conditions. The second step utilizes transition metal catalysts as well as waste-derived catalysts containing Fe, Co, and/or Ni (such as steel slag, mine tailing, and other solid wastes) for methane decomposition to produce solid carbons, such as graphite, carbon nanotubes and carbon nanofibers growing on the catalyst surface or catalyst support surface while generating hydrogen as a valuable byproduct. The solid carbon produced through this process serve as reinforcement materials for different applications, such as high-performance composites including silicon carbide, diamond, stainless steel, ceramic matrices, and concrete. The present disclosure uniquely integrates CO₂ utilization with waste material valorization while producing high-value materials for advanced applications, thereby addressing environmental challenges while creating economic value.

There are at least three unique aspects to the present disclosure. First, enhanced low-temperature CO₂ methanation is achieved using sol-gel derived nickel-based catalysts. Second, methane decomposition is achieved over transition metal catalysts. Third, an integrated system achieves both these benefits.

### Aspect 1: Enhanced Low-Temperature CO₂ Methanation using Sol-Gel Derived Nickel-Based Catalysts

Low-temperature carbon dioxide methanation has emerged as a promising technology for simultaneously addressing greenhouse gas emissions and renewable energy storage challenges. This process, which converts CO₂ to methane using hydrogen, traditionally requires temperatures above 350° C. for commercial catalysts to achieve satisfactory conversion rates. Recent breakthroughs in catalyst design, particularly through innovative preparation methods and materials selection, have enabled remarkable performance at substantially lower temperatures, enhancing the energy efficiency and economic viability of this process.

Nickel remains the preferred metal for CO₂ methanation catalysts due to its excellent balance of activity, selectivity, and cost. Significant progress has been made in enhancing nickel-based catalysts' activity at low temperatures through careful optimization of support materials and preparation methods. A notable breakthrough has been achieved with a robust Ni/ZrO₂ catalyst that demonstrates exceptional low-temperature CO₂ methanation performance even at 230° C., achieving 84.0% CO₂ conversion with 98.6% CH₄ selectivity at a gas hourly space velocity (GHSV) of 12,000 mL·g⁻¹·h⁻¹ for 106 hours. This represents one of the best performance metrics reported to date for nickel-based catalysts, especially considering that most commercial catalysts require temperatures above 350° C. The remarkable activity stems from reconstructing monoclinic-ZrO₂ supported nickel species with abundant oxygen vacancies, which facilitates CO₂ activation through enhanced local electron density of nickel induced by strong metal-support interactions. Similarly, NiAl—MO (metal oxide)/CeO₂ catalyst has demonstrated impressive results with 91% CO₂ conversion at 250° C. The incorporation of CeO₂ provides appropriate basic sites and oxygen vacancies that are conducive to improved catalytic performance at lower temperatures. The presence of ceria creates suitable metal-support interactions that benefit CO₂ methanation reactions.

The sol-gel synthesis approach has emerged as a particularly effective method for preparing high-performance low-temperature methanation catalysts. This preparation technique offers significant advantages for creating catalysts with optimized structural and electronic properties. High-loading Ni/SiO₂ catalysts (up to 50 wt. %) prepared via sol-gel methods have also shown excellent results, achieving high specific activity of 10.2 μmol_{CH4}·g⁻¹·s⁻¹ at 300° C. with 96% selectivity to CH₄ and 79% CO₂ conversion. Through careful synthesis control, small nickel particles (<5 nm) with high dispersion can be obtained within a highly porous silica matrix even at these substantial metal loadings.

In this disclosure, a series of nickel-based catalysts were prepared using a sol-gel method. The design and synthesis approach were systematically investigated, indicating the critical influence of support selection, nanoparticle morphology, and electronic configurations on low-temperature catalytic activity. This work examined how oxygen vacancy concentration, surface basicity, metal dispersion uniformity, and metal-support interfacial phenomena significantly impact overall catalyst efficiency, presenting an innovative pathway for catalyst development in this field.

### Aspect 2: Methane Decomposition over Transition Metal Catalysts

Methane decomposition, also known as methane cracking or methane pyrolysis, represents a promising approach for the production of hydrogen gas and valuable carbon nanomaterials while minimizing greenhouse gas emissions. This process involves the direct conversion of methane into its elemental components: hydrogen and solid carbon, without the formation of carbon dioxide or other greenhouse gases as byproducts. This reaction is moderately endothermic, requiring energy input to break the strong C—H bonds. The decomposition process follows Le Chatelier's principle, with low pressure and high temperature favoring the forward reaction. Non-catalytic thermal decomposition of methane requires temperatures of 900° C. or higher, while catalytic approaches can significantly reduce this temperature requirement to 500-750° C., making the process more economically viable.

Various transition metals have demonstrated catalytic activity for methane decomposition, with nickel, iron, and cobalt being among the most effective and widely studied. These metals can be used in their pure form or supported on various materials to enhance their performance and stability. Catalyst support materials play a crucial role in determining catalyst performance by influencing metal dispersion, surface area, and metal-support interactions. Common supports include Al₂O₃, SiO₂, TiO₂, ZrO₂, and carbonaceous materials, such as graphite, carbon fibers, and carbon nanotubes. The synthesis method also significantly impacts catalyst performance, with sol-gel, wet impregnation, fusion, and coprecipitation being common preparation techniques. Recent advancements include the development of bimetallic catalyst systems, such as Pd-promoted Ni catalysts, which have shown improved performance and stability during methane decomposition. Additionally, carbon-based catalysts have been explored for methane decomposition under contactless induction heating, demonstrating an autocatalytic effect where the carbon deposited during the reaction becomes the active phase for continued decomposition.

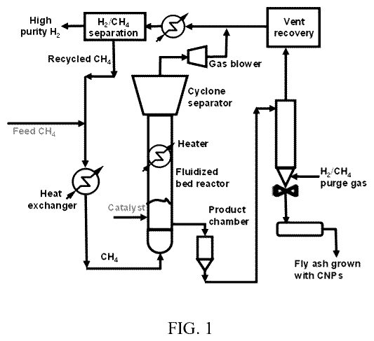

The fluidized bed reactor can run in a continuous mode. The system is schematically shown in FIG. 1. This methane pyrolysis reactor runs at atmospheric pressure. Catalyst particles may be added at the bottom of the reactor. H₂/CH₄ in the gas stream may be separated using a highly selective membrane to produce high purity H₂ (>99%) and unreacted CH₄ may be recycled back for pyrolysis.

In the context of producing high-quality CNTs through the catalytic decomposition of CH₄, a crucial step involves the removal of CNTs from the spent catalyst surface and the opening of their tips. This process is typically accomplished through an acid washing treatment, which serves two primary purposes: detaching the CNTs from the catalyst support and removing any residual metal encapsulations present at the CNT tips. During the CH₄ decomposition reaction, CNTs are formed on the surface of the catalyst, with their growth originating from the metal nanoparticles acting as nucleation sites. However, after the reaction, the CNTs remain attached to the catalyst surface, and their tips may be closed or encapsulated by residual metal particles. To obtain high-quality CNTs suitable for various applications, it is essential to liberate them from the catalyst surface and ensure open tips. The acid washing treatment typically involves exposing the spent catalyst to a strong acid solution, such as hydrochloric acid (HCl) or nitric acid (HNO₃), at elevated temperatures. After the acid washing step, the CNTs are typically subjected to thorough rinsing and drying processes to remove any residual acid and obtain a purified CNT product with open tips. These open-ended CNTs exhibit enhanced properties and are more suitable for applications such as field emission devices, energy storage, and composite reinforcement, where efficient charge transport or access to the CNT interior is desirable. The generated Ni(NO₃)₂ or NiCl₂ will be recycled to prepare Ni catalyst for the CH₄ decompositon reaction.

### Aspect 3. The Integrated System

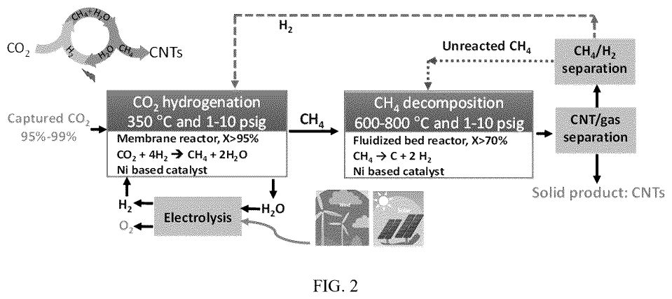

The disclosed process (FIG. 2) includes three steps to convert CO₂ to CNPs: (1) CO₂ hydrogenation to form CH₄ (i.e., methane) using a catalytic reactor, (2) CH₄ catalytic decomposition to form CNPs and H₂, and (3) separation of H₂ and unreacted CH₄, which will be recycled for CO₂ hydrogenation and CH₄ decomposition, respectively, as shown in FIG. 2. H₂O produced in the first reaction can be used to produce H₂ and O₂ via electrolysis using renewable electricity. CH₄ is selected as the intermediate because of the high conversion and high yield of products in both reactions.

Source of additional hydrogen for CO₂ hydrogenation: Though H₂ from CH₄ decomposition will be separated and recycled for CO₂ hydrogenation, additional 50% of H₂ needs to be provided, due to the converting of H₂ to water in the CO₂ hydrogenation process. The additional H₂ can be produced using electrolysis of water recycled in the process using renewable electricity. Electricity could also be generated by using the highly quality >300° C. steam generated in the CO₂ hydrogenation reaction, which is a highly exothermic reaction.

The proposed tandem catalytic processes using CH₄ as an intermediate has significant advantages compared to the state-of-the-art technologies, as summarized in Table 1. There is no known report about converting CO₂ to solid carbon using CH₄ as an intermediate. The present high-performance nickel (Ni) based on catalysts for CH₄ synthesis and CH₄ decomposition can significantly increase the catalytic activity, catalyst lifetime, and CNPs yield (e.g., g_{CNP}/g_{catalyst}). In addition, the two steps of the process are both gas-solid heterogeneous thermal catalysis, which are more suitable to operate continuously and easier to scale up. The catalysts used in the process are all non-noble metal.

TABLE 1
Comparison of CO₂-absorbing cement and construction product
technologies.

| | | | Production rate |
|---|---|---|---|
| Technology | Nature | Product | and scalability |
| Direct | Electrolysis | CNTs | Batch reaction, |
| electrolysis | in molten | | low scalability |
| | Li₂CO₃ | | |
| Direct | Ga-based | Low value | Batch reaction, |
| thermocatalysis | liquid metals | carbon | low scalability |
| Electro-Thermo | Separated two step | CNFs | Combination of |
| tandem catalysis | reaction | | two different |
| | | | technologies, |
| | | | non-continuous |
| This disclosure | Thermo-catalytic | CNTs or | Continuous |
| | reactions | CNFs | operation, easy to |
| | | | scale up |

Exemplary unique features of the present disclosure include the following:

Converting CO₂ to solid carbon using CH₄ as an intermediate, which is a highly efficient, highly scalable continuous process.

Using highly efficient catalysts for methane synthesis via CO₂ hydrogenation and methane decomposition to form CNTs and H₂, which can be recycled for methane synthesis.

Directly growing CNTs on particle surface to form CNTs/particle composites, which can be directly used to form some composite materials. This approach can solve CNTs dispersion issue in composites. Applications include growing CNTs on mine tailing particles, which can be used in concrete, growing CNTs on diamond particles and SiC particles, which can be used to form superhard, advanced functional composite materials.

### EXAMPLES

Without further elaboration, it is believed that one skilled in the art using the preceding description can utilize the present invention to its fullest extent. The following Examples are, therefore, to be construed as merely illustrative, and not limiting of the disclosure in any way whatsoever. The starting material for the following Examples may not have necessarily been prepared by a particular preparative run whose procedure is described in other Examples. It also is understood that any numerical range recited herein includes all values from the lower value to the upper value. For example, if a range is stated as 10-50, it is intended that values such as 12- 30, 20-40, or 30-50, etc., are expressly enumerated in this specification. These are only examples of what is specifically intended, and all possible combinations of numerical values between and including the lowest value and the highest value enumerated are to be considered to be expressly stated in this application.

### Example 1. Ni—MgO Catalyst Prepared by a Sol-Gel Method for Low Temperature CO₂ Methanation

### Catalyst Preparation.

Ni—MgO catalysts with a 10 wt. % nominal Ni loading were prepared by three synthesis methods: (i) sol-gel (SG), (ii) incipient wetness impregnation (IW), and (iii) coprecipitation (CP). For the SG method, appropriate quantities of nickel(II) nitrate hexahydrate (Ni(NO₃)₂·6H₂O) and magnesium nitrate hexahydrate (Mg(NO₃)₂·6H₂O) precursors were dissolved in deionized water, followed by the addition of an aqueous citric acid solution in a metal ion to citric acid molar ratio of 1:1.5. The resulting mixture was vigorously stirred at 80° C. to facilitate gelation. The obtained gel was subsequently dried overnight at 130° C. to acquire the precursor material as a yellow-green foam before final calcination in air at 600° C. for 2 hours (2° C./min heating rate) to yield the Ni—MgO—SG catalyst. A pure MgO was also synthesized by SG method, denoted as MgO-SG. For the IW approach, a MgO support material was impregnated with an aqueous solution of Ni(NO3)₂·6H₂O overnight before drying at 110° C. and calcining in air at 600° C. for 2 hours (2° C./min heating rate) to achieve the Ni—MgO—IW catalyst. Lastly, for the CP pathway, aqueous solutions of Ni and Mg nitrate and sodium hydroxide (NaOH) were simultaneously added dropwise into vigorously stirred water at 400 rpm while maintaining a pH of ˜12. The collected precipitate was repeatedly washed with warm deionized water before drying overnight at 110° C. and calcination in air at 600° C. for 2 hours (2° C./min heating rate) to obtain the Ni—MgO—CP catalyst.

### Catalytic Performance in CO₂ Methanation.

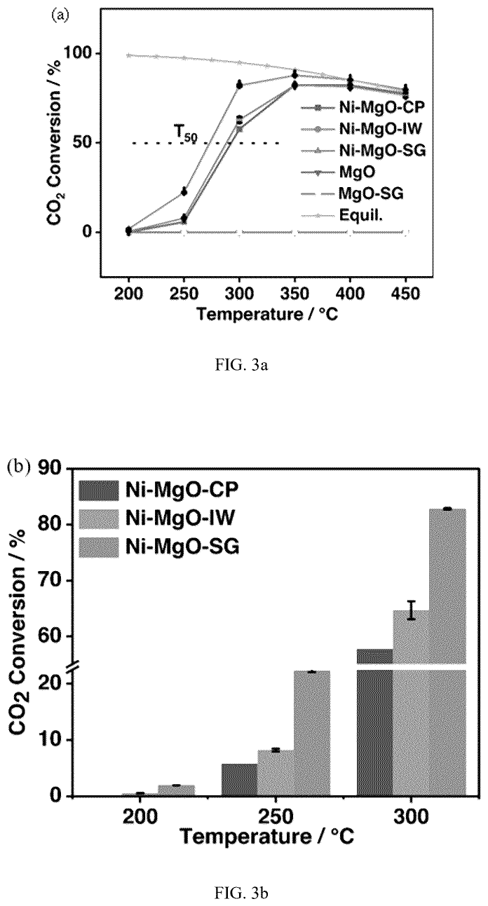

FIG. 3a illustrates the CO₂ conversion from 200 to 450° C. for Ni—MgO catalysts synthesized via different methods. All catalysts displayed a similar trend, with CO₂ conversion increasing from 200 to 350° C., then decreasing from 400 to 450° C., constrained by thermodynamic equilibrium limitations. Except for Ni—MgO—CP, which displayed a 97% selectivity towards CH₄, all other catalysts exhibited nearly 100% selectivity for CH₄ production. For CO₂ methanation, Ni—MgO—SG outperformed all other catalysts across the tested temperature range, especially below 300° C. The T₅₀ (Temperature at which 50% conversion is achieved) of Ni—MgO—SG (273° C.) was 20° C. lower than Ni—MgO—CP (293° C.). As evidenced in FIG. 3b, Ni—MgO—SG achieved 2% CO₂ conversion at 200° C., rapidly increasing to 22% at 250° C., whereas Ni—MgO—CP showed no conversion at 200° C. and only 5.7% at 250° C. Catalysts prepared by IW also surpassed Ni—MgO—CP but underperformed relative to Ni—MgO—SG. TOF_{CO2} (TOF=Turnover Frequency) provides insights into the intrinsic activity of the catalysts. The obtained TOF_{CO2} values for Ni—MgO—SG, Ni—MgO—IW, and Ni—MgO—CP were 0.15 s⁻¹, 0.12 s⁻¹, and 0.06 s⁻¹, respectively. The superior performance exhibited by Ni—MgO—SG can be attributed to its smaller nickel particle size of 6.1 nm, compared to 11.2 nm and 17.2 nm for the Ni—MgO—IW and Ni—MgO—CP samples, respectively. Previous research has demonstrated that smaller particle sizes facilitated an improved distribution of nickel particles, and highly dispersed nickel species promoted efficient hydrogen dissociation, generating an abundance of surface-dissociated hydrogen species. These surface hydrogen species play a crucial role in mitigating the formation of surface nickel carbonyls, thereby effectively enhancing the low-temperature activity for CO₂ methanation. In summary, comprehensive comparison of all synthetic methods revealed Ni—MgO—SG as the optimal catalyst formulation for enhanced CO₂ methanation at low temperature.

Due to its superior performance, Ni—MgO—SG was selected to investigate the effects of pressure and GHSV on CO₂ methanation. As shown in FIG. 4, under constant pressure, CO₂ conversion decreased with increasing GHSV from 9 to 36 L·g⁻¹·h⁻¹, likely due to the shorter residence time at higher GHSV. Pressure also significantly impacted CO₂ methanation, especially over the range of 14.5-150 psi. For instance, at 9 L·g⁻¹·h⁻¹, CO₂ conversion rose from 82.6% to 94.9% when pressure increased from 14.5 psi to 150 psi. The positive influence of elevated pressure was even more pronounced at higher GHSV, with conversion increasing from 72.3% to 90.6% over the same pressure range at 18 ·g⁻¹·h⁻¹. However, further increasing pressure from 150 psi to 300 psi only marginally improved conversion from 94.9% to 95.6% at 9 L·g⁻¹·h⁻¹, as the reaction began to approach thermodynamic equilibrium limitations. In summary, both GHSV and pressure demonstrated notable effects on CO₂ methanation over Ni—MgO—SG, with higher pressure significantly enhancing conversion, especially for operation at high gas hourly space velocities.

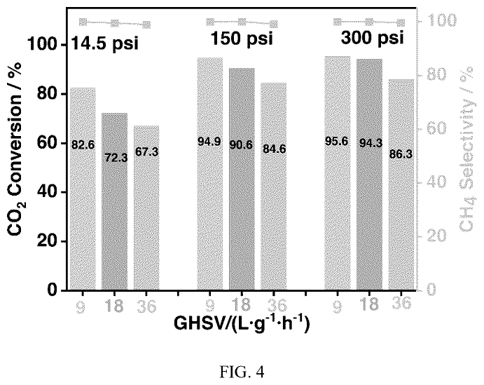

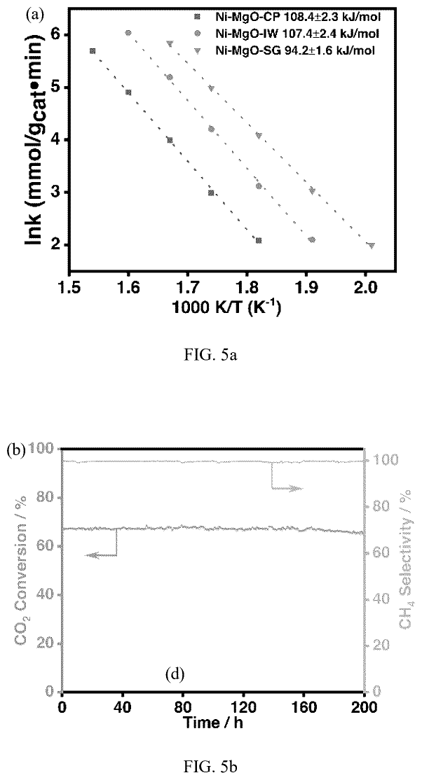

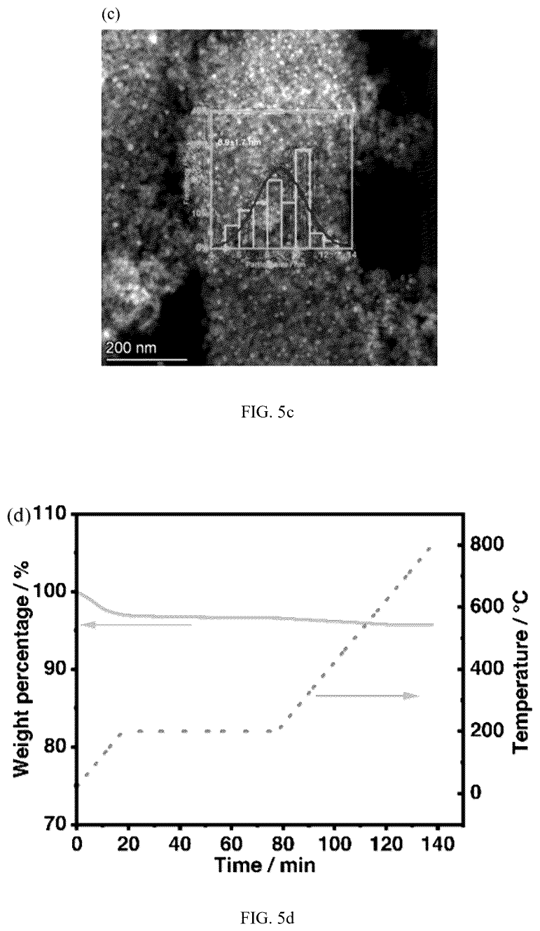

The apparent activation energies (Ea) of the Ni—MgO catalysts were determined from Arrhenius plots. The CO₂ conversion was maintained below 20% during the kinetic experiment. The Ea for CO₂ methanation, calculated from the Arrhenius plots in FIG. 5a over Ni—MgO—CP, Ni—MgO—IW, and Ni—MgO—SG, are 108.4±2.3, 107.4±2.4, and 94.2±1.6 kJ/mol, respectively. These Ea values are consistent with literature values reported for other Ni-based catalysts, including 75-118 kJ/mol for Ni/γ-Al₂O₃, 53.5-113 kJ/mol for Ni/CeO₂, and 94-116 kJ/mol for Ni—MgO. Of the tested Ni—MgO catalysts, Ni—MgO—SG exhibited the lowest Ea of 94.2±1.6 kJ/mol, indicating the lowest CO₂ activation energy barrier and the highest reaction rate. This aligned with the experimental results in FIG. 3, showing that Ni—MgO—SG had the highest catalytic activity. In contrast, Ni—MgO—CP had the highest Ea of 108.4±2.3 kJ/mol and the lowest catalytic activity.

The stability test for the Ni—MgO—SG sample was conducted at a high GHSV of 36 L·g⁻¹·h⁻¹at 300° C. for 200 hours. As shown in FIG. 5b, the CH₄ selectivity was above 99% in the tested conditions, while the CO₂ conversion dropped slightly from ˜67% to ˜65%. The high stability came from the formation of Ni—MgO solid solution. In this case, TEM imaging of the Ni—MgO—SG sample after stability testing in FIG. 5c revealed Ni nanoparticles remaining uniformly distributed, with a slight particle size increase from 6.1 nm to 8.9 nm. TGA (Thermogravimetric Analysis) was utilized to quantify carbon deposition on the spent Ni—MgO—SG catalyst after 200 hours of stability testing. The results are presented in FIG. 5d. Prior to analysis, the catalysts underwent a 200° C. preheating for 1 hour to eliminate any moisture adsorbed on sample surface. During subsequent temperature ramping from 200 to 800° C., the mass of the Ni—MgO—SG catalyst decreased from 96.6 wt. % to 95.7 wt. %, indicative of 0.9 wt. % carbonaceous residue detection. This minor coke accumulation suggests the Ni—MgO solid solution effectively inhibited coke formation. This enhanced stability is attributed to facile reaction of CO₂ adsorbed on the MgO support with deposited carbon, coupled with strong metal-support interactions preserving the Ni dispersion.

### Example 2. Ni₈₇Ce_{6.5}Zr_{6.5} Catalyst Prepared by a Sol-Gel Method for Low Temperature CO₂ Methanation

### Catalyst Preparation.

The Ni₈₇Ce_{6.5}Zr_{6.5}O₂ catalyst was synthesized via a modified sol-gel method. Stoichiometric amounts of Ni(NO₃)₂·6H₂O, Ce(NO₃)₃·6H₂O, and ZrO(NO₃)₂·xH₂O were dissolved in deionized water to achieve a final molar ratio of Ni:Ce:Zr=87:6.5:6.5. An aqueous citric acid solution was introduced as a chelating agent. The solution was maintained under vigorous stirring at 80° C. until gel formation occurred. The resultant gel underwent desiccation at 130° C. for 12 hours, yielding a yellow-green foam precursor. The final catalyst was obtained through thermal treatment in static air at 400° C. for 3 hours.

### Catalytic Performance in CO₂ Methanation.

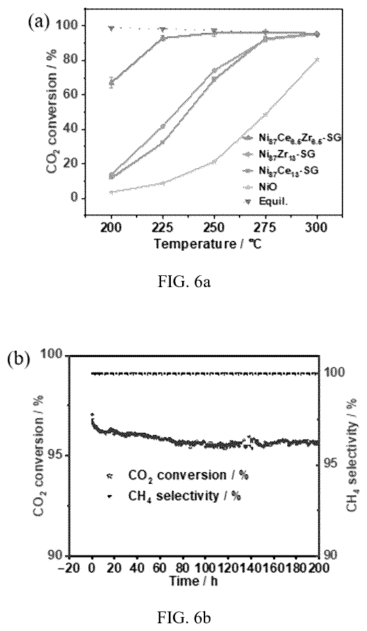

As illustrated in FIG. 6a, the Ni₈₇Ce_{6.5}Zr_{6.5}—SG catalyst demonstrated superior catalytic performance, achieving 67.1% CO₂ conversion at 200° C., significantly outperforming NiO (3.6%), Ni₈₇Ce₁₃—SG (11.6%), and Ni₈₇Zr₁₃—SG (13.7%). Elevated reaction temperatures further enhanced activity, with CO₂ conversion reaching 93% at 225° C. and 95.9% at 250° C., approaching the thermodynamic equilibrium conversion of 97.4%. Moreover, this catalyst also exhibited good stability, as shown in FIG. 6b, where CO₂ conversion gradually decreased from 97% to 96% over the first 48 hours and very slowly to 95.5% over the next 152 hours. Over the tested 200 hours, the catalyst only experienced a 1.5% decrease in CO₂ conversion, indicating notable stability. This exceptional performance underscores the synergistic role of Ce and Zr dopants in enhancing Ni dispersion, stabilizing active sites, and suppressing deactivation pathways, positioning Ni₈₇Ce_{6.5}Zr_{6.5}—SG as a promising candidate for low-temperature CO₂ methanation.

### Example 3. Stable Core-Shell Ni@xAl₂O₃ Catalyst for Enhanced Methane Decomposition

### Catalyst Preparation.

The Ni@xAl₂O₃ catalyst for methane decomposition was synthesized through a carefully designed two-stage preparation method. The Ni@xAl₂O₃ catalysts were subsequently prepared using an ion-exchange inverse loading (IEIL) strategy. The Ni(OH)₂ nanosheets were dispersed in a deionized water solution (60 mL) containing varying quantities of aluminum nitrate (2, 6, or 10 g), with continuous stirring at 500 rpm. The reaction mixture was then transferred to a 100-mL Teflon-lined stainless-steel autoclave, sealed, and hydrothermally treated at 120° C. for 12 hours. Upon cooling to room temperature, the resulting precipitate was collected by centrifugation, extensively washed with deionized water, and dried at 80° C. overnight. A final calcination step in static air at 400° C. for 2 hours yielded a gray powder. By modulating the Al³⁺/Ni(OH)₂ molar ratio, Ni@xAl₂O₃ catalysts with varying nickel loading and shell thicknesses were successfully produced, where ‘x’ represents the quantity of aluminum nitrate while maintaining a constant Ni(OH)₂ mass. For comparative purposes, a Ni/Al₂O₃ catalyst with similar nickel content was prepared via the conventional deposition-precipitation method, labeled as Ni/Al₂O₃-DP.

### Catalytic Performance in Methanation Decomposition.

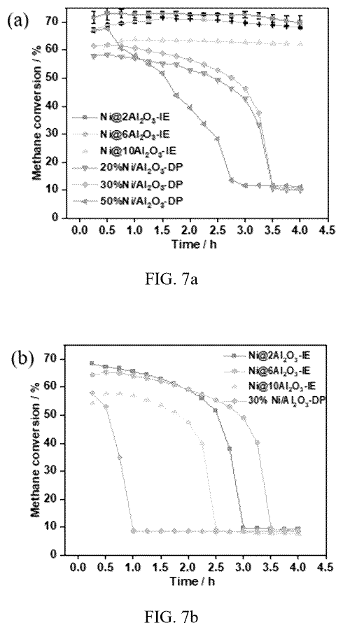

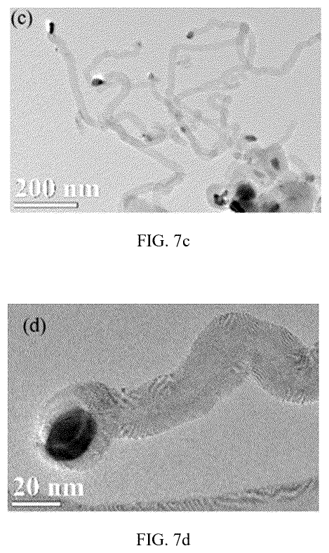

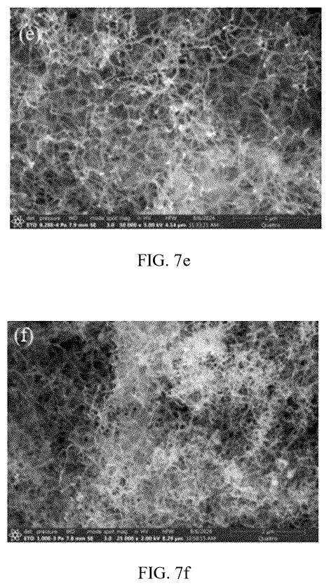

Methane pyrolysis concurrently generates high-value carbon materials (e.g., carbon nanofibers, nanotubes). The practical implementation faces challenges, including high energy demands, catalyst deactivation via carbon deposition, and precise control of carbon growth. Heterogeneous catalysts (Fe, Ni, Co) suffer rapid deactivation, while carbon-based catalysts (CNTs, activated carbon) require elevated temperatures. Molten metal systems enable facile carbon separation but produce amorphous, metal-contaminated carbon at high operational temperatures and scales. In this work, a Ni@Al₂O₃ core-shell catalyst, synthesized via an ion-exchange method (Ni@Al₂O₃-IE), demonstrated enhanced activity and stability for methane pyrolysis. As shown in FIG. 7a, Ni@Al₂O₃-IE outperformed a conventional deposition-precipitation (DP) catalyst, while Ni@Al₂O₃-IE (FIG. 7b) exhibited optimal performance under high GHSV, attributed to its balanced metal-support interaction and carbon diffusion kinetics. TEM (Transmission Electron Microscopy) images in FIGS. 7c and 7d as well as SEM (Scanning Electron Microscopy) images in FIGS. 7e and f confirmed the formation of carbon nanotubes.

### Example 4. CNTs Grown on Diamond Particles

Diamond, composed entirely of sp³-bonded carbon atoms, possesses a remarkable combination of properties that make it highly desirable for numerous applications. Its tremendous chemical inertness, extreme hardness, biocompatibility, unique electrochemical characteristics, large bandgap, and negative electron affinity when hydrogen-terminated render diamond an exceptional material. However, diamond faces significant processing limitations that inhibit its direct integration into many prospective applications. In contrast, carbon nanotubes, tubular structures formed from graphite sheets with 100% sp²-bonded carbon, exhibit a distinct set of exceptional properties. These include large thermal conductivity, high electron mobility, excellent electrical conductivity, and dual band-gap properties that can be either metallic or semiconducting depending on their chirality. Carbon nanotubes are considered among the most promising carbon forms for implementation in numerous nanoscale device applications, leveraging their remarkable qualities. The combination of carbon nanotubes and diamond presents an opportunity to create hybrid materials with unprecedented properties. These hybrids can potentially harness the advantages of both components, exhibiting excellent electrical and thermal conductivities, as well as field emission characteristics comparable to or surpassing those of pure diamond. This is due to the fact that pure diamond, without hydrogen termination, has inherently limited electrical conductivities. The synergistic effects of diamond and carbon nanotubes in these hybrid structures may open up a wide range of applications that require a unique blend of exceptional mechanical, thermal, and electrical properties. Potential fields of application include electronics, field emission devices, load transfer applications, and any domain that could benefit from the combination of diamond's and carbon nanotubes' complementary strengths.

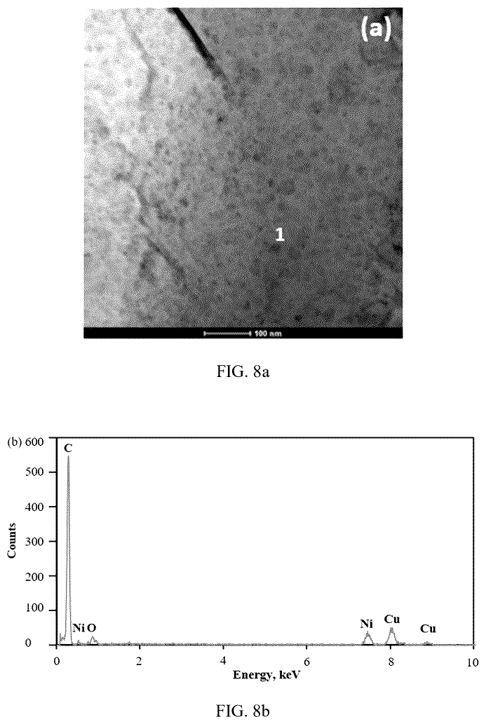

While the combination of CNTs and diamond holds immense potential, a significant challenge lies in obtaining a uniform distribution of CNTs on the diamond surface, as well as achieving strong adhesion forces between the CNTs and diamond. Compounding this challenge is the fact that diamond lacks the ability to decompose carbon-bearing molecules such as methane and ethanol, which makes it more difficult to obtain a desirable CNT/diamond composite. In this research, these challenges were addressed by first depositing nickel particles, a well-known catalyst for CNT growth, on the surface of diamond using liquid-or gas-based methods. One example of the gas-based method is atomic layer deposition (ALD) method. The ALD technique offers a distinct advantage in enabling a uniform distribution and precise control over the size of the deposited nickel particles (FIG. 8). This uniform and controlled distribution of nickel particles on the diamond surface is crucial for facilitating subsequent CNT growth. The obtained Ni/diamond composite was then utilized as a substrate for CNT growth, employing methane as the feed gas. By leveraging the catalytic properties of the deposited nickel particles, this approach overcomes the limitation of diamond's inability to decompose carbon-bearing molecules, enabling the successful growth of CNTs on the diamond surface.

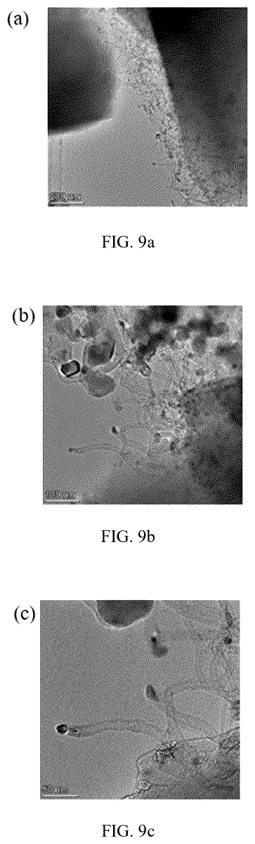

TEM analysis of the CNT/diamond composite reveals crucial insights into the morphology and characteristics of the grown CNTs. As evidenced by FIG. 9, the diamond surface is successfully covered by a layer of vertically aligned CNTs, demonstrating the effectiveness of the employed growth process. Quantitative analysis of the TEM images indicates that the grown CNTs exhibit inner diameters of 8.6±1.2 nm and outer diameters of 12.7±3.2 nm, respectively. This narrow distribution of diameters suggests a relatively uniform growth process, which is a desirable characteristic for potential applications that may require specific dimensional constraints. Notably, the TEM images also reveal the presence of nickel (Ni) particles at the tips of the CNTs. These Ni particles served as catalysts during the CNT growth process, facilitating the decomposition of the methane feed gas and the subsequent formation of CNTs. The observation of Ni particles at the tips is indicative of a tip growth mechanism, which is a common growth mode for CNTs on various substrates. The tip growth mechanism offers several advantages for the CNT/diamond composite. First, it allows for a strong anchoring of the CNTs to the diamond surface, as the CNTs grow from the catalytic Ni particles that are initially deposited on the diamond substrate. This strong adhesion is crucial for ensuring the structural integrity and stability of the composite material under various operating conditions. Furthermore, the presence of Ni particles at the tips of the CNTs provides an opportunity for post-growth purification. By subjecting the composite to an acid washing treatment, the exposed Ni particles can be selectively removed, resulting in a high purity of CNTs on the diamond surface. This purification step is essential for applications that may require pristine CNTs without the presence of residual catalytic particles. Additionally, the acid washing treatment can potentially open the walls of the CNTs, creating opportunities for functionalization or filling the CNTs with desired materials. This capability could further expand the range of potential applications for the CNT/diamond composite, leveraging the unique properties of both materials in synergistic ways.

### Example 5. CNTs Growth on Stainless-Steel Particles

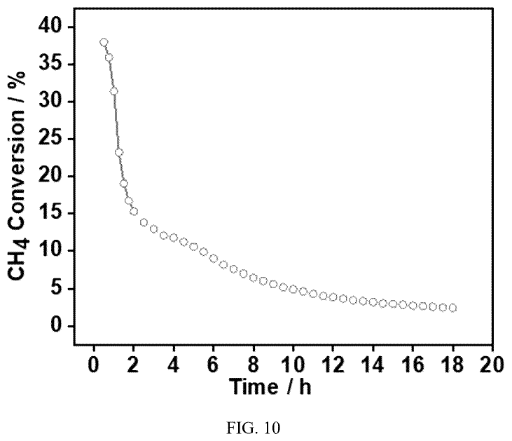

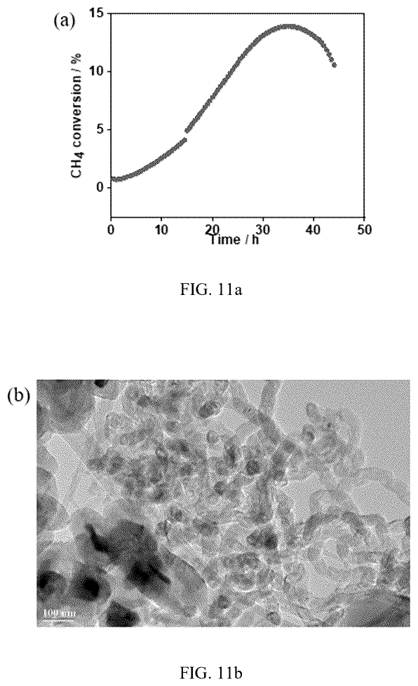

Stainless steel nanoparticles have emerged as promising catalysts for methane decomposition, offering an economically viable alternative to traditional noble metal catalysts. These nanoparticles exhibit exceptional catalytic activity due to the synergistic effects between constituent elements such as iron, chromium, and nickel. The use of stainless steel nanoparticles in methane decomposition also aligns with the global transition towards sustainable energy solutions. This process provides a cleaner alternative to traditional hydrogen production methods, such as steam methane reforming, which generates significant CO₂ emissions. Moreover, the solid carbon byproduct can be repurposed for various industrial applications, including battery electrodes and composite materials, adding economic value to the process. As illustrated in FIG. 10, methane conversion utilizing stainless steel particles at 800° C. exhibited an initial efficiency of 38% during the first hour of operation. However, a significant decline in catalytic activity was observed over time, with conversion rates diminishing to approximately 3% after 18 hours of continuous processing. For CNTs reinforcing purpose, the amount of CNTs grown on stainless-steel particles is high enough with one hour of reaction time. Therefore, long-term catalytic stability is not necessary.

### Example 6. CNTs Growth on Steel Wool

Steel wool has demonstrated promising efficacy as a catalyst for methane decomposition, offering a cost-effective alternative to conventional noble metal catalysts. The iron oxide present in steel wool provides active sites that facilitate the breaking of C—H bonds in methane molecules, resulting in carbon deposition and hydrogen gas production. This heterogeneous catalytic process typically operates at temperatures between 700-900° C., where the high surface area of steel wool's fibrous structure maximizes contact with methane gas, enhancing reaction kinetics. As illustrated in FIG. 11a, methane conversion demonstrated a progressive increase, reaching its peak value of 14% after 36 hours of continuous operation. Complementary TEM analysis presented in FIG. 11b confirmed that the carbonaceous products formed during this catalytic process were predominantly carbon nanotubes, as evidenced by their characteristic morphological features.

### Example 7. CNTs Growth on Waste Particles Containing Transient Metals, such as Steel Slags

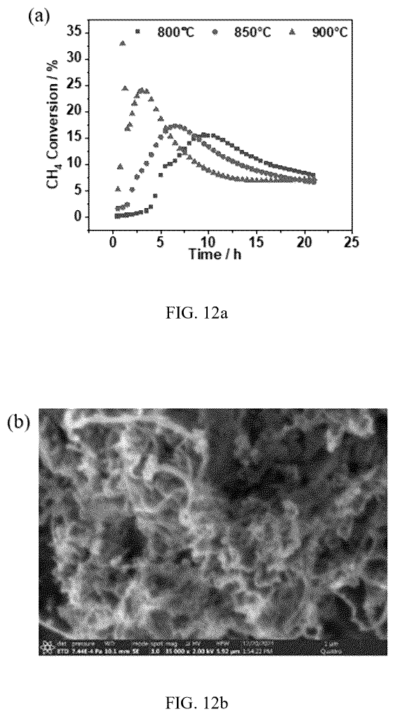

Steel slags have been explored as a cost-effective and sustainable catalyst for methane decomposition, offering a dual benefit of hydrogen production and industrial waste valorization. Rich in metal oxides, such as iron, calcium, and magnesium oxides, steel slags exhibit catalytic properties that facilitate the breakdown of methane into hydrogen and solid carbon. Their inherent porosity and thermal stability further enhance their performance, making them a viable alternative to conventional catalysts. By repurposing steel slags for methane decomposition, this approach not only reduces reliance on expensive catalytic materials but also contributes to the circular economy by transforming industrial wastes into valuable resources. As illustrated in FIG. 12a, methane conversion rates exhibited a distinctive pattern of initial increase followed by subsequent decline across all tested temperatures (800° C., 850° C., and 900° C.). The maximum conversion efficiencies were temperature-dependent, with peak values of 13%, 17%, and 26% achieved at 800° C., 850° C., and 900° C., respectively. Notably, the time required to reach these maximum conversion rates decreased with increasing temperature, occurring at 10 hours for 800° C., 5 hours for 850° C., and 3 hours for 900° C., demonstrating an inverse relationship between reaction temperature and time to peak conversion. FIG. 12b shows the SEM of the obtained solid carbon at 800° C. Over time, deactivation due to carbon deposition and structural degradation can reduce their efficiency. Solid wastes like steel slags have been used for cement or concrete procution. The inclusion of CNTs can significantly increase the mechanical property and conductivity of the concrete. For such CNTs reinforcing purpose, the amount of CNTs grown on such solid wastes with a few hours of reaction time is high enough. Therefore, long-term catalytic stability is not necessary for such applications.

### Example 8. Tandem Catalytic Conversion of CO₂ to CNTs

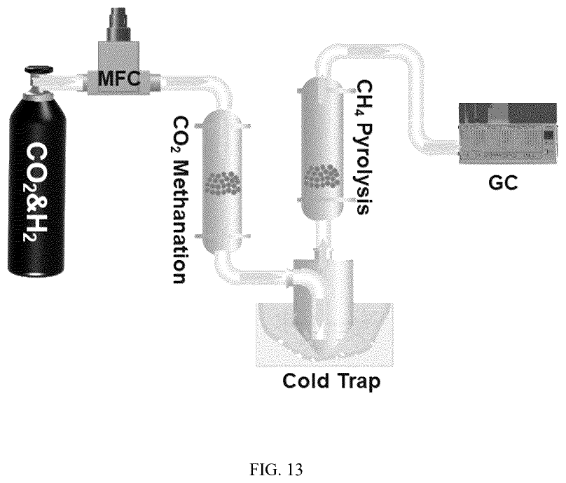

The conversion of CO₂ to CNTs was achieved through a two-reactor system, comprising CO₂ methanation followed by methane pyrolysis. The scheme of the system is shown in FIG. 13.

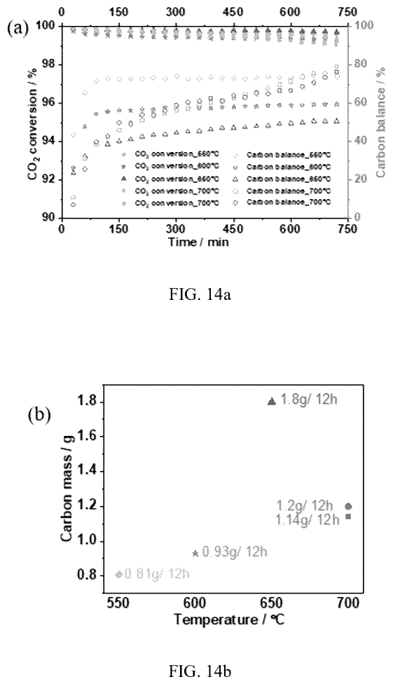

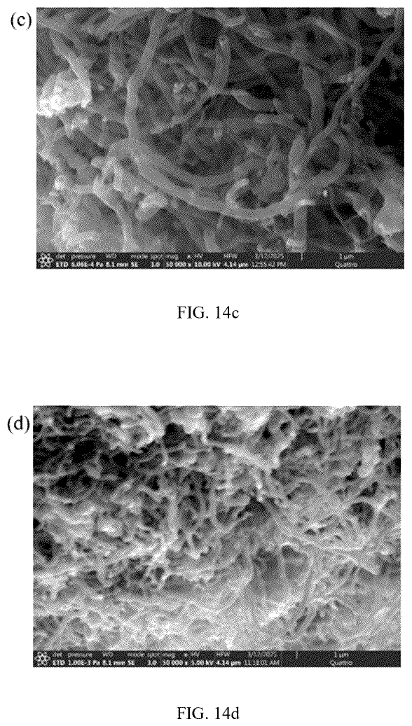

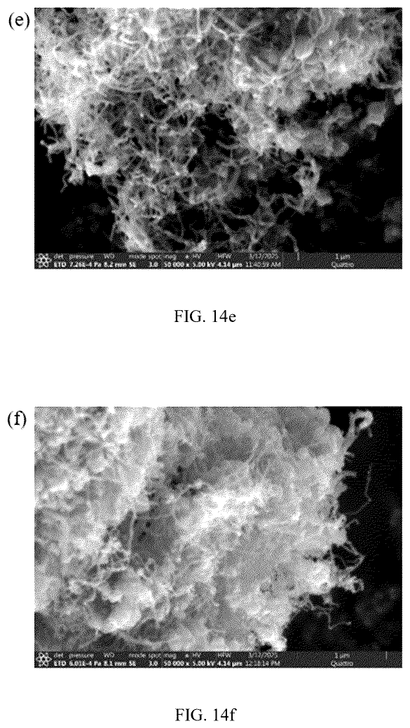

While the methanation reactor was maintained at a constant temperature of 250° C., the pyrolysis reactor temperature was systematically varied from 550° C. to 700° C. in 50° C. increments to examine its influence on CNT formation. Analysis of the reaction performance (FIG. 14a) revealed consistently high CO₂ conversion rates across all temperature conditions. Although a slight decrease in conversion efficiency was observed at 700° C., it remained above 98.5%. This minor reduction may be attributed to accelerated catalyst deactivation in the second reactor at elevated temperatures, given the fixed conditions in the first reactor. The gas-phase carbon balance served as an indicator of solid carbon deposition, where higher carbon balance values corresponded to lower carbon deposition rates. All temperature conditions exhibited a rapid increase in gas-phase carbon balance during the initial two hours of reaction. A lower gas-phase carbon balance means the higher yield of solid carbon. At 550° C. and 600° C., the carbon balance stabilized at approximately 73% and 57%, respectively, maintaining these levels for the subsequent 10 hours. However, at 650° C., a gradual increase from 39% to 50% was observed over the 10-hour period. The most dramatic change occurred at 700° C., where the balance rose substantially from 42% to 80%. As shown in FIG. 14b, the cumulative carbon mass yields after 12 hours of reaction were 0.81 g, 0.93 g, 1.8 g, and 1.3 g for temperatures of 550, 600, 650, and 700 ° C., respectively. While methane pyrolysis is endothermic, suggesting enhanced solid carbon formation at higher temperatures, the observed yield at 700° C. was lower than that at 650° C. This unexpected result can be attributed to rapid catalyst deactivation at 700° C., evidenced by the steep slope in FIG. 14a. These findings highlight that while higher temperatures can enhance methane pyrolysis thermodynamically, they also introduce challenges such as catalyst deactivation and parasitic reactions that reduce overall CNT yield. Optimal CNT production under these conditions was achieved at a pyrolysis temperature of 650° C., balancing efficient methane decomposition with minimal catalyst degradation and side reactions.

### Example 9. Carbon Nanotube/Nanofiber Reinforced Ceramic Nanocomposites

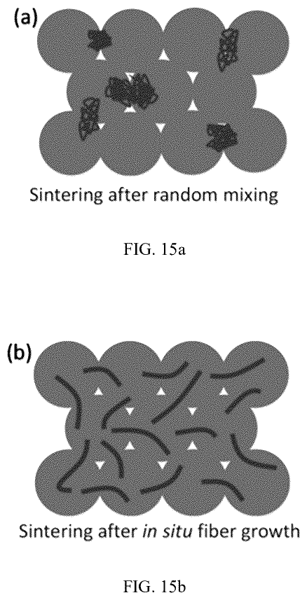

This disclosure is related to an advanced carbon nanotube (CNT) or carbon nanofiber (CNF) reinforced ceramic composite, such as silicon carbide (SiC), by spark plasma sintering (SPS) or high pressure high temperature (HPHT) sintering of ceramic matrix particles grown with CNTs or CNFs from gas phase deposition. Ceramic materials are relatively brittle. Adding carbon nanotubes or carbon nanofibers into ceramic is known to toughen the material. However, manufacturing of carbon fiber or nanotubes reinforced ceramic composites is challenging. In this disclosure, CNTs or CNFs will grow on individual ceramic particles by catalytic methane decomposition and then the particles will be sintered by SPS or HPHT sintering process. Non-uniformity of the second-phase material in conventional random mixing will be solved and the well-dispersed CNTs or CNFs will significantly increase the toughness of ceramic materials, as schematically shown in FIG. 15. The disclosure has a potential to provide a cost-effective strategy for manufacturing advanced ceramic matrix composites with superior properties.

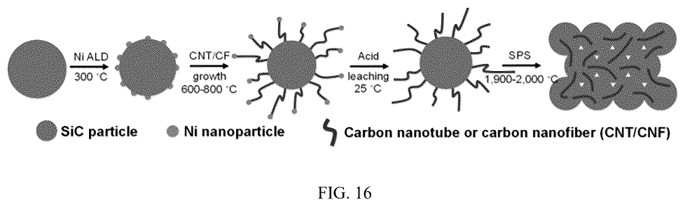

Using SiC as one example. The technology includes four steps: (1) deposition of highly dispersed Ni nanoparticle (NP) catalysts on SiC particles by atomic layer deposition (ALD, which can deposit highly dispersed metal nanoparticles on substrate surface through chemical bonding), (2) growth of CNTs on SiC particles using methane decomposition catalyzed by Ni NPs at 600-800° C., (3) leaching Ni NPs from SiC/CNT particles using acid solution, and (4) SPS of SiC particles with CNTs grown uniformly on the SiC particles surface at 800-2000° C., as schematically shown in FIG. 16. Due to the growth mechanism of CNTs by CH₄ decomposition, CNTs will be chemically bonded on the SiC particles surface and Ni NPs will be on the tip of CNTs. So, the acid leaching of Ni will not affect the structure of CNTs on SiC. After SPS, the CNTs will be homogeneously distributed in the matrix of SiC. SiC grain growth would be limited due to secondary-phase pinning effect and crack development would be inhibited by the added CNTs. The proposed strategy is universal and can be applied to other composites using CNTs or CNFs as a reinforcing agent.

### Embodiments.

Further aspects of the invention are provided by the subject matter of the following clauses. These clauses may be combined in any permutation or combination.

A Ni—MgO catalyst comprising nickel particles, wherein the nickel particles have an average diameter of less than about 100 nanometers, less than about 90 nanometers, less than about 80 nanometers, less than about 70 nanometers, less than about 60 nanometers, less than about 50 nanometers, less than about 40 nanometers, less than about 30 nanometers, less than about 20 nanometers, or less than about 10 nanometers.

The Ni—MgO catalyst of the preceding clause, wherein the nickel particles have an average diameter of less than about 10 nanometers, less than about 8 nanometers, less than about 5 nanometers, or less than about 2 nanometers.

The Ni—MgO catalyst of any preceding clause, wherein the Ni—MgO catalyst is prepared via a sol-gel method.

The Ni—MgO catalyst of any preceding clause, wherein the Ni—MgO catalyst has a CO₂ methanation T₅₀ of less than about 350° C. at atmospheric pressure or less than about 300° C. at atmospheric pressure.

The Ni—MgO catalyst of any preceding clause, further comprising a metal oxide.

The Ni—MgO catalyst of any preceding clause, wherein the Ni—MgO catalyst has a BET specific surface area of at least 10 m²/g.

The Ni—MgO catalyst of any preceding clause, wherein the Ni—MgO catalyst has a BET specific surface area of at least 100 m²/g.

The Ni—MgO catalyst of any preceding clause, wherein the Ni—MgO catalyst has a high CH₄ selectivity and high CO₂ conversion. In these embodiments, high selectivity means greater than 70%, greater than 75%, greater than 80%, greater than 85%, greater than 90%, greater than 95%, greater than 98%, or up to 100% selectivity. In these embodiments, high conversion means greater than 70%, greater than 75%, greater than 80%, greater than 85%, greater than 90%, greater than 95%, greater than 98%, or up to 100% conversion.

A method of using the Ni—MgO catalyst of any preceding clause, the method comprising using the Ni—MgO catalyst for methanating CO₂ to form CH₄.

The method of the preceding clause, wherein methanating CO₂ occurs at a temperature in a range of from about 200° C. to about 450° C.

A NiCeZr—SG catalyst comprising nickel particles, wherein the nickel particles have an average diameter of less than about 100 nanometers, less than about 90 nanometers, less than about 80 nanometers, less than about 70 nanometers, less than about 60 nanometers, less than about 50 nanometers, less than about 40 nanometers, less than about 30 nanometers, less than about 20 nanometers, or less than about 10 nanometers.

The NiCeZr—SG catalyst of the preceding clause, wherein the nickel particles have an average diameter of less than about 20 nanometers, less than about 12 nanometers, less than about 7 nanometers, or less then about 2 nanometers.

The NiCeZr—SG catalyst of any preceding clause, wherein the NiCeZr—SG catalyst has an element content of nickel of from about 60 to about 90, an element content of cerium of from about 2 to about 20, and/or an element content of zirconium of from about 2 to about 20.

The NiCeZr—SG catalyst of any preceding clause, wherein the NiCeZr—SG catalyst has a formula of Ni₈₇Ce_{6.5}Zr_{6.5}—SG.

The NiCeZr—SG catalyst of any preceding clause, wherein the NiCeZr—SG catalyst is prepared via a sol-gel method.

The NiCeZr—SG catalyst of any preceding clause, wherein the NiCeZr—SG catalyst has a CO₂ methanation T₅₀ of less than about 350° C. at atmospheric pressure or less than about 300° C. at atmospheric pressure.

The NiCeZr—SG catalyst of any preceding clause, further comprising a metal oxide.

The NiCeZr—SG catalyst of any preceding clause, wherein the NiCeZr—SG catalyst has a BET specific surface area of at least 10 m²/g.

The NiCeZr—SG catalyst of any preceding clause, wherein the NiCeZr—SG catalyst has a BET specific surface area of at least 100 m²/g.

The NiCeZr—SG catalyst of any preceding clause, wherein the NiCeZr—SG catalyst has a high CH₄ selectivity and high CO₂ conversion. In these embodiments, high selectivity means greater than 70%, greater than 75%, greater than 80%, greater than 85%, greater than 90%, greater than 95%, greater than 98%, or up to 100% selectivity. In these embodiments, high conversion means greater than 70%, greater than 75%, greater than 80%, greater than 85%, greater than 90%, greater than 95%, greater than 98%, or up to 100% conversion.

A method of using the NiCeZr—SG catalyst of any preceding clause, the method comprising using the NiCeZr—SG catalyst for methanating CO₂ to form CH₄.

A core-shell Ni@Al₂O₃ catalyst comprising:
a core comprising Ni particles; and
a shell comprising Al₂O₃, wherein the shell has a thickness in a range of from about 0.5 nm to about 50 nm.

The core-shell Ni@Al₂O₃ catalyst of the preceding clause, wherein the core-shell Ni@Al₂O₃ catalyst is prepared via an ion-exchange method.

A method of using the core-shell Ni@Al₂O₃ catalyst of any preceding clause, the method comprising using the core-shell Ni@Al₂O₃ catalyst for decomposing CH₄.

The method of the preceding clause, wherein decomposing CH₄ forms at least one product selected from the group consisting of H₂, carbon nanoproducts, carbon nanotubes, carbon nanofibers, carbon nanoparticles, graphene, amorphous carbon, carbon nano-onions, spherical carbon, carbon dots, graphite, carbon soot, carbon black, and combinations thereof.

The method of any preceding clause, wherein the Ni-containing catalyst is in a form of a molten metal.

A catalyst composition comprising nickel nanoparticles embedded in a core-shell structure of aluminum oxide (Al₂O₃).

The catalyst of the preceding clause, wherein the catalyst comprises a further metal selected from the group consisting of copper, cerium, aluminum, and combinations thereof.

The catalyst of any preceding clause, wherein the catalyst comprises one or more of enhanced activity, improved stability, and enhanced anti-coking properties relative to compared to a catalyst composition comprising nickel nanoparticles embedded on a conventional support.

A method of converting CO₂ to solid carbon, the method comprising two reaction steps, wherein methane is an intermediate.

The method of the preceding clause, wherein the method comprises a first step of catalytically methanating CO₂ to form CH₄ and a second step of catalytically decomposing CH₄ to form nanoproducts (CNPs) and H₂.

The method of the preceding clause, wherein the first step and the second step utilize different catalysts.

A method to produce carbon nanoproducts (CNPs), comprising:
catalytically methanating CO₂ to form CH₄, wherein catalytically methanating CO₂ to form CH₄ comprises using a Ni—MgO catalyst comprising nickel particles having an average diameter of about <100 nm;
catalytically decomposing CH₄ to form CNPs and H₂, wherein catalytically decomposing CH₄ to form CNPs and H₂ comprises using a core-shell Ni@Al₂O₃ catalyst comprising:
a core comprising Ni particles; and
a shell comprising Al₂O₃, wherein the shell has a thickness in a range of from about 0.5 nm to about 50 nm;
separating H₂ and unreacted CH₄; and
recovering the CNPs.

A method to produce carbon nanoproducts (CNPs), comprising:
catalytically methanating CO₂ to form CH₄, wherein catalytically methanating CO₂ to form CH₄ comprises using a NiCeZr—SG catalyst comprising nickel particles having an average diameter of about <100 nm;
catalytically decomposing CH₄ to form CNPs and H₂, wherein catalytically decomposing CH₄ to form CNPs and H₂ comprises using a core-shell Ni@Al₂O₃ catalyst comprising:
a core comprising Ni particles; and
a shell comprising Al₂O₃, wherein the shell has a thickness in a range of from about 0.5 nm to about 50 nm;
separating H₂ and unreacted CH₄; and
recovering the CNPs.

A method to produce a composite, comprising:
depositing highly dispersed nanoparticle (NP) catalysts on substrate particles,
growing carbon nanotubes (CNTs) on the substrate particles using CH₄ decomposition catalyzed by the NPs to form CNT-particles,
leaching the NP catalysts from the CNT-particles using an acid solution, and
sintering the CNT-particles to form a composite including CNTs grown uniformly on surfaces of the substrate particles of the composite.

A method comprising:
depositing catalytic particles on substrate particles, and
using the catalytic particles to grow carbon nanoproducts on the substrate particles.

The method of the preceding clause, wherein the particles of the substrate particles comprise diamonds.

The method of any preceding clause, wherein the catalytic particles are deposited on the substrate particles with a liquid phase-based growth method or a gas phase-based growth method.

The method of any preceding clause, wherein the catalytic particles are deposited on the substrate particles with atomic layer deposition.

The method of any preceding clause, wherein the carbon nanoproducts are selected from the group consisting of carbon nanotubes, carbon nanofibers, carbon nanoparticles, graphene, amorphous carbon, carbon nano-onions, spherical carbon, carbon dots, graphite, carbon soot, carbon black, and combinations thereof.

The method of the preceding clause, wherein the NP catalysts are selected from the group consisting of nickel (Ni) nanoparticles, carbon, iron (Fe), cobalt (Co), copper (Cu), platinum (Pt) and palladium (Pd), ruthenium (Ru), rhodium (Rh), iridium (Ir), rhenium (Re), tungsten (W), and molybdenum (Mo), and combinations thereof.

The method of any preceding clause, wherein the substrate particles are selected from the group consisting of ceramic particles, SiC particles, diamond particles, steel particles, stainless steel particles, iron particles, chromium particles, nickel particles, steel wool, steel slags, mine tailing, concrete, silicon nitride (Si₃N₄), alumina oxide (Al₂O₃), zirconium oxide (ZrO₂), titanium carbide (TiC), boron carbide, tungsten carbide, boron nitride, aluminum nitride, and combinations thereof.

A method to produce a composite, comprising:
depositing highly dispersed nanoparticle (NP) catalysts on substrate particles to form CNT-substrate particles, and
directly dispersing the CNT-substrate particles in a composite precursor to form the composite.

The method of the preceding clause, wherein composite precursor is selected from the group consisting of polymer composites, CNT-reinforced polymer composites, solid composites, and combinations thereof.

The method of any preceding clause, wherein the composite includes the CNT-substrate particles as a filler or reinforcing agent.

The method of the preceding clause, wherein the NP catalysts are selected from the group consisting of nickel (Ni) nanoparticles, carbon, iron (Fe), cobalt (Co), copper (Cu), platinum (Pt) and palladium (Pd), ruthenium (Ru), rhodium (Rh), iridium (Ir), rhenium (Re), tungsten (W), and molybdenum (Mo), and combinations thereof.

A composite, comprising:
carbon nanoproducts uniformly deposited on surfaces of substrate particles.

The composite of the preceding clause, wherein uniformity is defined as a coefficient of variation of less than 50% for the density of carbon nanotubes across different regions of the substrate.

The composite of any preceding clause, wherein uniformity is defined as a coefficient of variation of less than 10% for the density of carbon nanotubes across different regions of the substrate.

The composite of any preceding clause, wherein the carbon nanoproducts are selected from the group consisting of carbon nanotubes, carbon nanofibers, graphite, and combinations thereof.

The composite of any preceding clause, wherein the carbon nanoproducts have an average inner diameter less than about 10 nm and an average outer diameter less than about 15 nm.

The composite of any preceding clause, wherein the carbon nanoproducts have an average inner diameter in the range of about 5 nm to about 300 nm and an average outer diameter in the range of about 10 nm to about 300 nm.

The composite of any preceding clause, wherein the carbon nanoproducts have an average inner diameter in the range of about 5 nm to about 100 nm and an average outer diameter in the range of about 10 nm to about 100 nm.

The composite of any preceding clause, wherein the substrate particles are selected from the group consisting of ceramic particles, SiC particles, diamond particles, steel particles, stainless steel particles, iron particles, chromium particles, nickel particles, steel wool, steel slags, mine tailing, concrete, silicon nitride (Si₃N₄), alumina oxide (Al₂O₃), zirconium oxide (ZrO₂), titanium carbide (TiC), boron carbide, tungsten carbide, boron nitride, aluminum nitride, and combinations thereof.

A method of using the composite of any preceding clause, the method comprising using the composite in an application selected from the group consisting of electronics, field emission devices, load transfer applications, biomedical applications, energy storage material applications, aerospace and automotive industry applications, environmental applications, construction industry applications, and combinations thereof. It is understood that CNT-enhanced materials have a wide range of applications across various industries due to their exceptional mechanical, thermal, and electrical properties. For example, in construction, they can strengthen building materials and improve thermal insulation. In energy and aerospace, CNTs enhance energy storage, thermal management, and create lightweight yet robust components. Biomedically, CNTs are used in drug delivery systems and tissue engineering. In electronics, they serve as conductive films and interconnects. Automotive and sports industries benefit from CNT-enhanced composites that reduce weight while improving durability. Additionally, CNTs are used in environmental applications such as water purification and electromagnetic interference shielding. Overall, CNT-enhanced materials offer significant improvements in performance, efficiency, and sustainability across multiple sectors.

### Definitions

As used herein, references to “example embodiment” or “one embodiment” or “some embodiments” of the present disclosure are not intended to be interpreted as excluding the existence of additional embodiments that also incorporate the recited features.

When introducing elements of various embodiments disclosed herein, the articles “a,” “an,” “the,” and “said” are intended to mean that there are one or more of the elements. The terms “comprising,” “including,” and “having” are intended to be inclusive and mean that there may be additional elements other than the listed elements.

Unless otherwise indicated, approximating language, such as “generally,” “substantially,” and “about,” as used herein indicates that the term so modified may apply to only an approximate degree, as would be recognized by one of ordinary skill in the art, rather than to an absolute or perfect degree. Accordingly, a value modified by a term or terms such as “about,” “approximately,” and “substantially” is not to be limited to the precise value specified. In at least some instances, the approximating language may correspond to the precision of an instrument for measuring the value. Additionally, unless otherwise indicated, the terms “first,” “second,” etc. are used herein merely as labels, and are not intended to impose ordinal, positional, or hierarchical requirements on the items to which these terms refer. Moreover, reference to, for example, a “second” item does not require or preclude the existence of, for example, a “first” or lower-numbered item or a “third” or higher-numbered item.

Although specific features of various embodiments of the invention may be shown in some drawings and not in others, this is for convenience only. In accordance with the principles of the invention, any feature of a drawing may be referenced and/or claimed in combination with any feature of any other drawing.

While the invention has been described in terms of various specific embodiments, those skilled in the art will recognize that the invention can be practiced with modification within the spirit and scope of the claims.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A method of converting CO₂ to solid carbon, the method comprising:
a first step of catalytically methanating CO₂ to form CH₄; and
a second step of catalytically decomposing the CH₄ to form carbon nanoproducts (CNPs) and H₂.

2. The method of claim 1, wherein the first step and the second step utilize different catalysts.

3. The method of claim 1, wherein the first step utilizes a catalyst selected from the group consisting of Ni—MgO catalysts, NiCeZr—SG catalysts, and combinations thereof.

4. The method of claim 3, wherein the catalyst comprises nickel particles having an average diameter of less than about 100 nanometers.

5. The method of claim 1, wherein the second step utilizes a catalyst selected from the group consisting of core-shell Ni@Al₂O₃ catalysts, waste-derived catalysts containing Fe, Co, and/or Ni, steel slag-derived catalysts, mine tailing-derived catalysts, solid waste-derived catalysts, and combinations thereof.

6. The method of claim 1, wherein the second step utilizes a core-shell Ni@Al₂O₃ catalyst.

7. The method of claim 5, wherein the core-shell Ni@Al₂O₃ catalyst comprises a core comprising Ni particles and a shell comprising Al₂O₃, wherein the shell has a thickness in a range of from about 0.5 nm to about 50 nm.

8. The method of claim 1, further comprising:
separating H₂ and unreacted CH₄; and
recovering the CNPs.

9. The method of claim 1, wherein the carbon nanoproducts are selected from the group consisting of carbon nanotubes, carbon nanofibers, carbon nanoparticles, graphene, amorphous carbon, carbon nano-onions, spherical carbon, carbon dots, graphite, carbon soot, carbon black, and combinations thereof.

10. A method comprising:
depositing catalytic particles on substrate particles; and
using the catalytic particles to grow carbon nanoproducts on the substrate particles.

11. The method of claim 10, wherein the substrate particles are selected from the group consisting of ceramic particles, SiC particles, diamond particles, steel particles, stainless steel particles, iron particles, chromium particles, nickel particles, steel wool, steel slags, mine tailing, concrete, silicon nitride (Si₃N₄), alumina oxide (Al₂O₃), zirconium oxide (ZrO₂), titanium carbide (TiC), boron carbide, tungsten carbide, boron nitride, aluminum nitride, and combinations thereof.

12. The method of claim 10, wherein the particles of the substrate particles comprise diamond particles.

13. The method of claim 10, wherein the catalytic particles are particles selected from the group consisting of nickel (Ni), carbon, iron (Fe), cobalt (Co), copper (Cu), platinum (Pt) and palladium (Pd), ruthenium (Ru), rhodium (Rh), iridium (Ir), rhenium (Re), tungsten (W), and molybdenum (Mo), and combinations thereof.

14. The method of claim 10, wherein the carbon nanoproducts are selected from the group consisting of carbon nanotubes, carbon nanofibers, carbon nanoparticles, graphene, amorphous carbon, carbon nano-onions, spherical carbon, carbon dots, graphite, carbon soot, carbon black, and combinations thereof.

15. A method to produce a composite, comprising:
depositing highly dispersed nanoparticle (NP) catalysts on substrate particles;
growing carbon nanoproducts (CNPs) on the substrate particles using CH₄ decomposition catalyzed by the NPs to form CNP-particles;
leaching the NP catalysts from the CNP-particles using an acid solution; and
sintering the CNP-particles to form a composite including CNPs grown uniformly on surfaces of the substrate particles of the composite.

16. The method of claim 15, wherein the substrate particles are selected from the group consisting of ceramic particles, SiC particles, diamond particles, steel particles, stainless steel particles, iron particles, chromium particles, nickel particles, steel wool, steel slags, mine tailing, concrete, silicon nitride (Si₃N₄), alumina oxide (Al₂O₃), zirconium oxide (ZrO₂), titanium carbide (TiC), boron carbide, tungsten carbide, boron nitride, aluminum nitride, and combinations thereof.

17. The method of claim 15, wherein the particles of the substrate particles comprise diamond particles.

18. The method of claim 15, wherein the catalytic particles are deposited on the substrate particles with a liquid phase-based growth method or a gas phase-based growth method.

19. The method of claim 15, wherein the carbon nanoproducts are selected from the group consisting of carbon nanotubes, carbon nanofibers, carbon nanoparticles, graphene, amorphous carbon, carbon nano-onions, spherical carbon, carbon dots, graphite, carbon soot, carbon black, and combinations thereof.

20. The method of claim 15, wherein the NP catalysts are particles selected from the group consisting of nickel (Ni), carbon, iron (Fe), cobalt (Co), copper (Cu), platinum (Pt) and palladium (Pd), ruthenium (Ru), rhodium (Rh), iridium (Ir), rhenium (Re), tungsten (W), and molybdenum (Mo), and combinations thereof.
